(19) United States
(12) Patent Application Publication
(10) Pub. No.: US 2013/0063139 A1
(43) Pub. Date: Mar. 14, 2013

(54) METHOD AND ITS APPARATUS FOR INSPECTING A MAGNETIC HEAD DEVICE

(71) Applicants: Teruaki TOKUTOMI, Kamisato (JP); Takeshi SATOH, Kamisato (JP); Akira TOBITA, Kamisato (JP); Naoya SAITOH, Kamisato (JP); Norimitsu MATSUSITA, Kamisato (JP)

(72) Inventors: Teruaki TOKUTOMI, Kamisato (JP); Takeshi SATOH, Kamisato (JP); Akira TOBITA, Kamisato (JP); Naoya SAITOH, Kamisato (JP); Norimitsu MATSUSITA, Kamisato (JP)

(73) Assignee: HITACHI HIGH-TECHNOLOGIES CORPORATION, Tokyo (JP)

(21) Appl. No.: 13/565,184

(22) Filed: Aug. 2, 2012

(30) Foreign Application Priority Data
Sep. 9, 2011 (JP) 2011-197145

(51) Int. Cl. G01R 33/12

(52) U.S. Cl. 324/212

(57) ABSTRACT

An apparatus for inspecting a magnetic head device inspects an effective track width of a write track of each of magnetic head devices formed on a row bar in order to measure a two-dimensional distribution of magnetic fields generated by the magnetic head devices formed on the row bar while the apparatus is not affected by an external environment. The apparatus has a tray unit, a stage unit, a sample receiving and delivering unit, a magnetic field measuring unit and an effective track width measuring unit on a vibration isolation unit that blocks a vibration from the outside of the apparatus. The tray unit, the stage unit, the sample receiving and delivering unit, the magnetic field measuring unit, the effective track width measuring unit and the vibration isolation table are covered with a sound insulation unit that blocks noise from the outside of the apparatus.

### BACKGROUND

The present invention relates to a method of and an apparatus for inspecting a magnetic head device. The invention more particularly relates to a method of and an apparatus for inspecting a magnetic head device adapted to measure an effective track width of a write track while a number of magnetic head devices formed on a substrate are held in a state of a row bar before separated during the process of manufacturing the magnetic head devices.

For devices operative to subject a magnetic head to non-destructive inspection, inspection methods that use the following microscopes are applied: an optical microscope, a scanning electron microscope (SEM), an atomic force microscope (AFM), and a magnetic force microscope (MFM).

Although the aforementioned methods have advantages or disadvantages, the method using the MFM is superior to the methods using the other microscopes in that it can inspect, in a non-destructive manner, a magnetic field generated by a magnetic head for data-writing on a hard disk.

For example, JP-2010-175534-A describes that an effective track width of a write track is measured using an MFM while magnetic head devices are held in a state of a row bar before separated. JP-2010-175534-A describes that a magnetic field is generated by applying current to a magnetic head circuit pattern of the row bar that is a sample, a magnetic probe attached to a cantilever is placed close to the generated magnetic field, and the magnetic field generated from the sample is measured by two-dimensionally scanning the cantilever over the field, thereby detecting the amount of displacement of the probe.

### SUMMARY

JP-2010-177534-A describes that a two-dimensional distribution of magnetic fields generated by the respective magnetic heads formed on the magnetic head row bar is measured by two-dimensionally scanning the cantilever provided with the probe over the field. JP-2010-177534-A, however, does not describe a device and method for setting the sample at a measurement position and performing the measurement with high accuracy without the sample being affected by an environment surrounding the sample.

The invention aims to provide a method and apparatus for inspecting a magnetic head device which solve the problem of the aforementioned conventional technique and allow measurement of a two-dimensional distribution of magnetic fields generated by respective magnetic head devices formed on a magnetic head row bar.

In order to solve the aforementioned problem, according to the invention, an apparatus for inspecting a magnetic head device inspects an effective track width of a write track of each of magnetic head devices formed on a row bar and includes: a tray unit that stores an inspected row bar and an uninspected row bar in a separate manner; a stage unit capable of moving between an inspection position and a sample reception/delivery position; a sample receiving and delivering unit that takes out the uninspected row bar from the tray unit and delivers the row bar to the stage unit waiting at the sample reception/delivery position; a magnetic field measuring unit in which an alternating current is applied to a magnetic head device formed on the uninspected row bar and a magnetic field generated therefrom is measured in a state where the stage unit that received the uninspected row bar at the sample reception/delivery position has moved to the inspection position; an effective track width measuring unit that determines, on the basis of data obtained from the measurement by the magnetic field measuring unit, whether or not an effective track width of a write track formed on the magnetic head device is valid; a vibration isolation table that mounts thereon the tray unit, the stage unit, the sample receiving and delivering unit, the magnetic field measuring unit and the effective track width measuring unit, the vibration isolation table adapted to block vibration from the outside of the apparatus; and a sound insulation unit that covers the tray unit, the stage unit, the sample receiving and delivering unit, the magnetic field measuring unit, the effective track width measuring unit, and the vibration isolation table to insulate noise from the outside of the apparatus

In order to solve the aforementioned problem, according to the invention, a method for inspecting a magnetic head device by inspecting an effective track width of a write track of each of magnetic head devices formed on a row bar includes the steps of: taking out an uninspected row bar from a supply tray and delivering the uninspected row bar to a stage waiting at a sample reception/delivering position; moving, to an inspection position, the stage that has received the uninspected row bar; moving up the uninspected row bar by means of the stage so that a gap between the uninspected row bar and a probe attached to a cantilever of a magnetic force microscope and located near an edge of the cantilever, while the stage has moved to the inspection position; applying an alternating current to one of magnetic head devices formed on the uninspected row bar to cause a magnetic field to be generated from the one of the magnetic head devices, and measuring the state of the generated magnetic field by means of the magnetic force microscope, while the uninspected row bar has been moved up; determining, on the basis of the measured state of the magnetic field, whether or not an effective track width of a write track formed on the one of the magnetic head devices is valid; moving down the row bar whose validity of the write track of the magnetic head is determined by means of the stage after the effective track width of the write track has been determined; using the stage to transport the validity determined row bar from the inspection position to the sample reception/delivery position after the validity determined row bar has been moved down; and storing, on the basis of the determination of whether the effective track width of the write track is valid, the validity determined row bar transported to the sample reception/delivery position on either a tray for storing a non-defective product or a tray for storing a defective product on a vibration isolation table for blocking a vibration from the outside of the apparatus in an environment in which the apparatus is covered with a sound insulation wall.

According to the invention, magnetic head devices formed on row bars can be inspected for magnetic properties in an environment in which surrounding noise and vibration are blocked, and defective row bars can be recovered separately from non-defective row bars. This makes it possible to enhance the manufacturing yield of the magnetic head devices.

These features and advantages of the invention will be apparent from the following more particular description of a preferred embodiment of the invention, as illustrated in the accompanying drawings.

### BRIEF DESCRIPTION OF THE DRAWINGS

FIG. 1 is a block diagram illustrating the whole configuration of an apparatus for inspecting a magnetic head device according to an embodiment of the present invention;

FIG. 2 is a plan view of a configuration of the apparatus for inspecting a magnetic head device according to the embodiment of the present invention;

FIG. 3 is a cross-sectional arrow view of an outline configuration of a measuring unit included in the apparatus for inspecting a magnetic head device according to the embodiment of the present invention, taken along line A-A of FIG. 2;

FIG. 4A is a perspective view of a row bar to be inspected according to the present invention;

FIG. 4B is a plan view of a magnetic head device, illustrating the state in which electrodes of the magnetic head device formed on the row bar contacts edges of a probe in the embodiment of the present invention;

FIG. 5 is a cross-sectional arrow view of an outline configuration of a transporting unit included in the apparatus according to the embodiment of the present invention, taken along line B-B of FIG. 2;

FIG. 6 is a block diagram illustrating an outline configuration of a control system for the measuring unit included in the apparatus for inspecting a magnetic head device according to the embodiment of the present invention; and

FIG. 7 is a flowchart of a process of inspecting a magnetic head device according to the embodiment of the present invention.

### DESCRIPTION OF THE PREFERRED EMBODIMENT

Hereinafter, an embodiment of the invention is described with reference to the accompanying drawings.

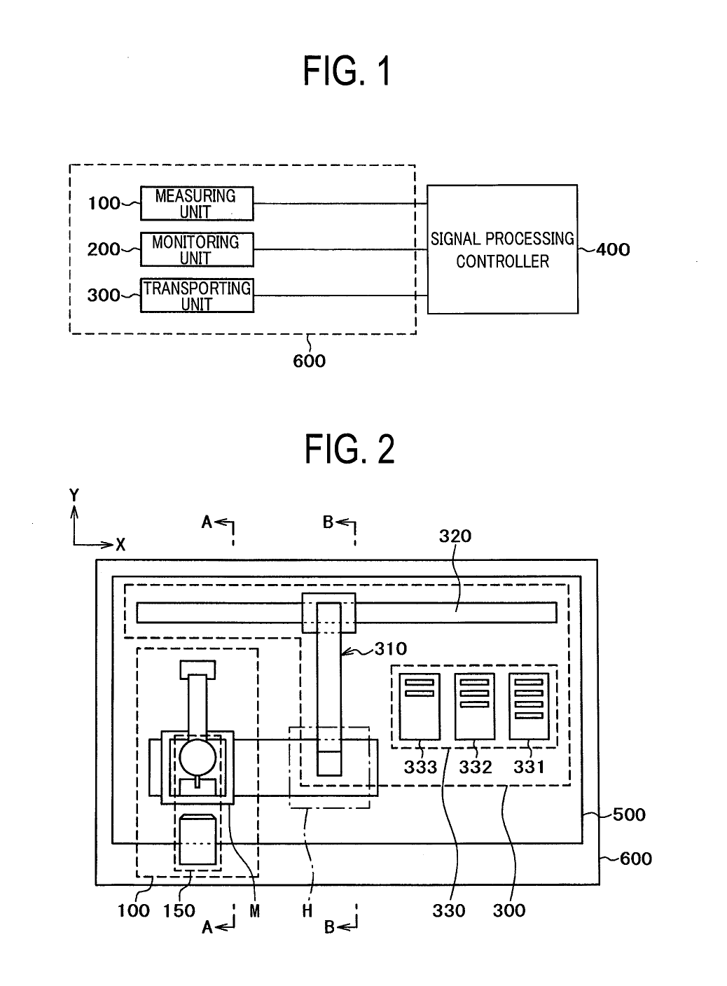

FIG. 1 is a block diagram illustrating the whole configuration of an apparatus for inspecting a magnetic head device according to the embodiment of the invention. The apparatus for inspecting a magnetic head device includes a measuring unit 100, a monitoring unit 200, a transporting unit 300 and a signal processing controller 400.

The measuring unit 100, the monitoring unit 200 and the transporting unit 300 are covered with a sound insulation box 600. The sound insulation box 600 blocks a sound coming from the outside of the apparatus so as to prevent a measurement from being affected.

FIG. 2 is a plan view of a configuration of the apparatus for inspecting a magnetic head device according to the embodiment of the present invention. In the apparatus for inspecting a magnetic head device, the measuring unit 100 and the transporting unit 300 are mounted on a vibration isolation table 500 that is covered with the sound insulation box 600.

The transporting unit 300 includes a transporting robot 310, a guide rail 320 and a tray holder 330. The guide rail 320 guides the transporting robot 310 moving in X direction. The tray holder 330 holds trays 331 to 333 for storing row bars thereon before and after the inspection.

A symbol H indicates a sample reception/delivery station, while a symbol M indicates a sample measurement station.

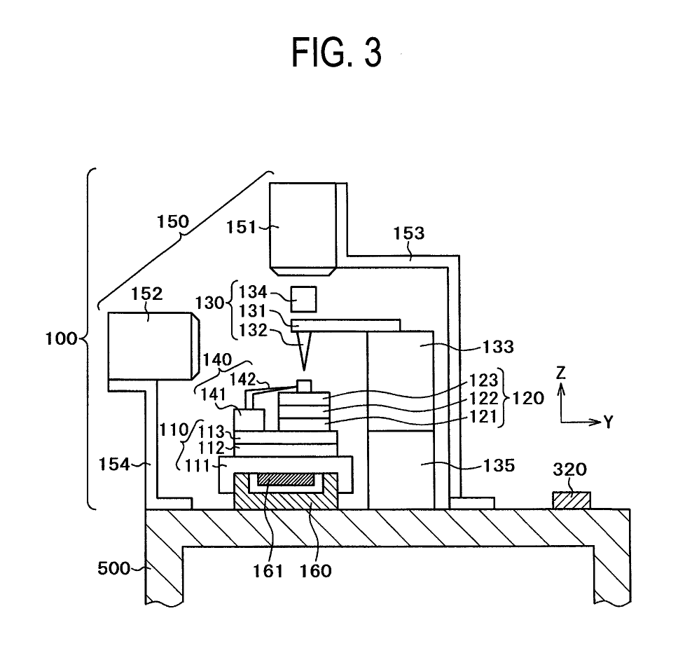

FIG. 3 is a cross-sectional arrow view taken along line A-A of FIG. 2 and illustrates a detailed configuration of the measuring unit 100. The measuring unit 100 includes an XYZ coarse movement stage unit 110, an XYZ fine movement stage unit 120, a first probe unit 130, a second probe unit 140, an observation unit 150 and an X axis guide rail 160.

The XYZ coarse movement stage unit 110 includes an X coarse movement stage 111, a Y coarse movement stage 112 and a Z coarse movement stage 113. The X coarse movement stage 111 is driven by a linear motor 161 and is thereby capable of moving along the X axis guide rail 160 in X direction between the sample reception/delivery station H and the sample measurement station M.

The XYZ fine movement stage unit 120 includes an X fine movement stage 121, a Y fine movement stage 122 and a Z fine movement stage 123. The X fine movement stage 121, the Y fine movement stage 122 and the Z fine movement stage 123 are driven by driving sources (for example, piezoelectric elements (not illustrated)) that have nanometer-order resolutions.

The first probe unit 130 includes a cantilever 131, a first probe 132, a vibration exciter 133, a position detector 134 and a vibration exciter base 135. The first probe 132 is attached to the cantilever 131 and located near a head of the cantilever 131. The vibration exciter 133 vibrates the cantilever 131. The position detector 134 detects a vibration of the cantilever 131. The vibration of the cantilever 131 is influenced by a vibration of the first probe 132 attached to the cantilever 131. The position detector 134 irradiates the cantilever 131 with an optical beam and detects light reflected from the cantilever 131. Then, an inclination angle of the cantilever 131 is detected on the basis of the position of the detected light and the amount of displacement of the first probe 132 is calculated. The first probe 132 is made of a magnetic material. The amplitude of the cantilever 131 varies depending on the intensity of a magnetic field to be measured. Thus, the measuring unit 100 functions as a magnetic force microscope (MFM).

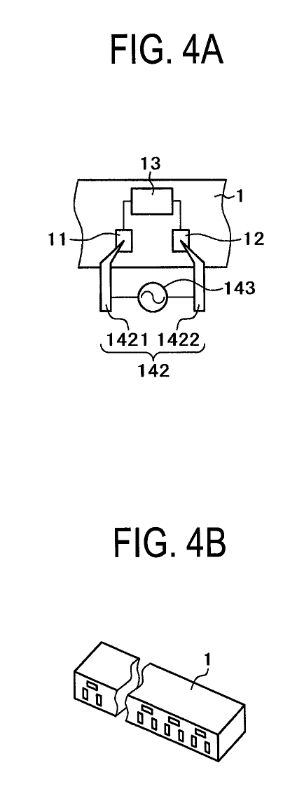

The second probe unit 140 includes a probe guard 141 and a second probe 142 which is attached to the probe guard 141. As illustrated in FIG. 4A, a row bar 1 is a substrate that is formed in a rectangular shape and has many magnetic head devices formed thereon. When probe electrodes 11 and 12 that are formed on the row bar 1 of the magnetic head devices are in contact with tips 1421 and 1422 of the second probe 142 as illustrated in FIG. 4B and an alternating current source 143 applies an alternating current to the tips 1421 and 1422 of the second probe 142, a magnetic field is generated from a writing circuit 13. When the frequency of the alternating current to be applied to the row bar 1 is set to be different from a resonance frequency of the cantilever 131, a distribution of magnetic fields generated from the row bar 1 can be measured at a high speed, and effective track widths of write tracks can be measured.

The probe guard 141 can be moved in Y direction by a configuration that is not illustrated. The probe guard 141 is driven so that the tips 1421 and 1422 of the second probe 142 contact and are separated from the probe electrodes 11 and 12.

The observation unit 150 includes a vertical observation camera 151 and a lateral observation camera 152. The vertical observation camera 151 observes the row bar 1 of the magnetic head devices and the cantilever 131. The lateral observation camera 152 observes the row bar 1 of the magnetic head devices and the tips 1421 and 1422 of the second probe 142. Reference numeral 153 indicates a camera holding member that holds the vertical observation camera 151 and is fixed to the vibration isolation table 500. Reference numeral 154 indicates a camera holding member that holds the lateral observation camera 152 and is fixed to the vibration isolation table 500.

The XYZ coarse movement unit 110 can roughly bring the first probe 132 at an observation position. The XYZ coarse movement unit 110 enables the first probe 132 to be retracted after a measurement of the row bar 1. The XYZ coarse movement unit 110 enables the XYZ fine movement stage unit 120 to be retracted for replacement of the row bar 1 or replacement of the first probe 132.

The XYZ fine movement stage unit 120 includes the piezoelectric elements (not illustrated) as the driving sources. Each of the driving sources has a sub-nanometer horizontal resolution and a sub-nanometer vertical resolution. Thus, the XYZ fine movement stage unit 120 can change gaps between the edges of the first probe 132 and an upper surface of the row bar 1 on a sub-nanometer scale. In addition, the XYZ fine movement stage unit 120 can change relative positions of the first probe 132 and row bar 1 in horizontal direction on a sub-nanometer scale.

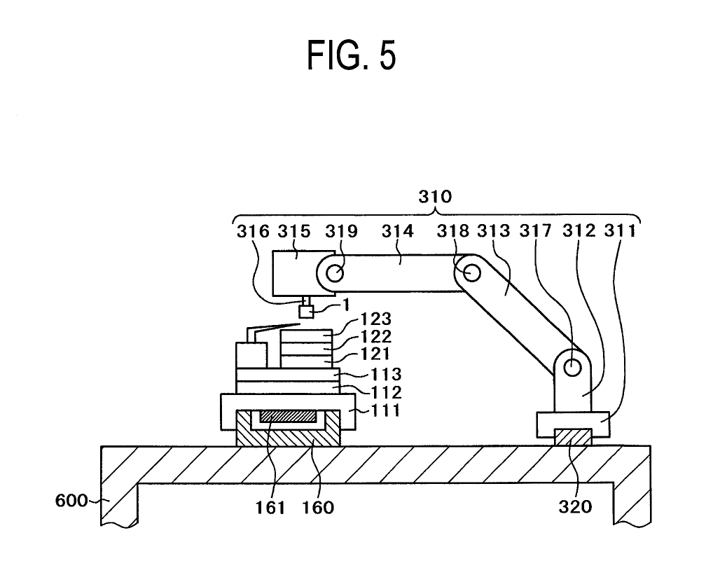

FIG. 5 is a cross-sectional arrow view taken along line B-B of FIG. 2. As illustrated in FIG. 5, the transporting robot 310 includes a base 311, a main frame 312, a first arm 313, a second arm 314, a work suction head unit 315, a work suction unit 316, a first joint unit 317, a second joint unit 318 and a third joint unit 319. The work suction unit 316 of the work suction head unit 315 vacuum-sucks the row bar 1 before and after inspection, and the transporting robot 310 transports the row bar 1 between a tray of the tray holder 330 and the measuring unit 100.

The transporting robot 310 may hang both ends of the row bar 1 on hooks (not illustrated) so as to move up or down the row bar 1 without using the work suction head unit 315 and the work suction unit 316.

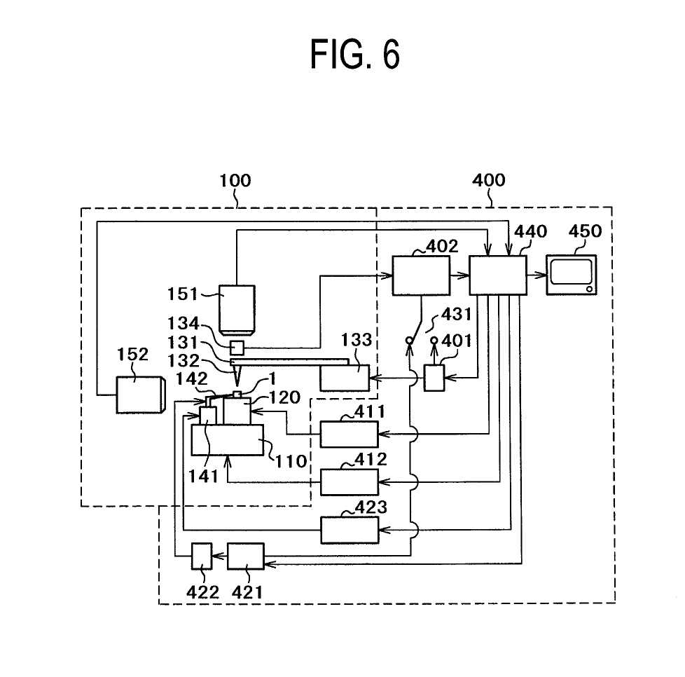

FIG. 6 illustrates an outline configuration of the measuring unit 100 and the signal processing controller 400, which includes a circuit to control the measuring unit 100 and process the signals detected by the measuring unit 100. The circuit that is included in the signal processing controller 400, controls the measuring unit 100 and processes the detected signal includes an oscillator 401, an amplifier 402, an XYZ fine movement stage controller 411, an XYZ coarse movement stage controller 412, a constant current source 421, a resistance measuring unit 422, a probe guard controller 423, a switch 431, a controller 440 and a display unit 450. The oscillator 401 excites the vibration exciter 133. The amplifier 402 amplifies a signal output from the position detector 134. The XYZ fine movement stage controller 411 controls the XYZ fine movement stage unit 120. The XYZ coarse movement stage controller 412 controls the XYZ coarse movement stage unit 110. The constant current source 421 applies a direct current to the second probe 142. The resistance measuring unit 422 measures a resistance between the tips 1421 and 1422 of the second probe 142. The probe guard controller 423 drives the probe guard 141 so as to move the probe guard 141 in a vertical direction and thereby control whether or not the tips 1421 and 1422 of the second probe 142 contact the electrodes 11 and 12 of the row bar 1. The switch 431 selects a signal output from the oscillator 401 or a signal output from the constant current source 421 and causes the selected signal to be input to the amplifier 402. The controller 440 performs signal processing and image processing and controls the whole of the signal processing controller 400.

When a lock-in amplifier is used as the amplifier 402, the switch 431 connects the amplifier 402 to the oscillator 401, and the lock-in amplifier is locked to an oscillation frequency of the oscillator 401, only a signal component caused by a vibration of the cantilever 131 can be selectively obtained.

When the switch 431 connects the amplifier 402 to the constant current source 421 and the lock-in amplifier is used as the amplifier 402 and locked to the frequency of the alternating current of the constant current source 421, a response of the cantilever 131 to excitation of a magnetic head device of the row bar 1 can be selectively detected from signals output from the position detector 134.

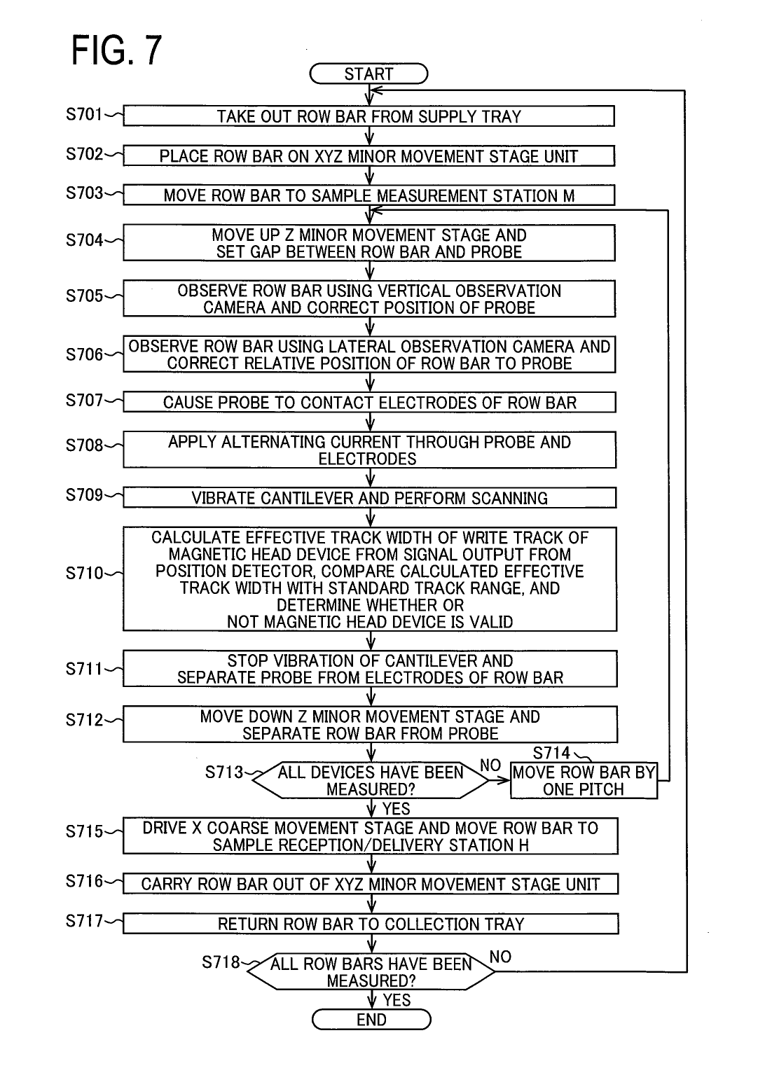

In this configuration, the transporting robot 310 takes out the row bar 1 from the supply tray 331 of the tray holder 330 and transports the row bar 1 to the measuring unit 100. The transporting robot 310 stores the row bar 1 measured by the measuring unit 100 on either the tray 332 for non-defective products or the tray 333 for defective products on the basis of a result of the measurement of the row bar 1. The series of operations from the taking of the row bar 1 by the transporting robot 310 to the storage of the measured row bar 1 by the transporting robot 310 are described with reference to FIG. 7.

First, the work suction unit 316 of the work suction head unit 315 vacuum-sucks the row bar 1 stored on the supply tray 331 of the tray holder 330 and whereby the transporting robot 310 takes out the row bar 1 from the supply tray 331 (S701). When the transporting robot 310 uses the hooks without the work suction unit 316 and the work suction head unit 315, the transporting robot 310 hangs both ends of the row bar 1 on the hooks and takes out the row bar 1 from the supply tray 331 (S701). Next, the transporting robot 310 moves along the guide rail 320 to the sample reception/delivery station H and places the row bar 1 on the XYZ fine movement stage unit 120 that waits at the sample reception/delivery station H and is located on the XYZ coarse movement stage unit 110 (S702). While the row bar 1 is placed on the XYZ fine movement stage unit 120, the XYZ coarse movement stage unit 110 is controlled by the XYZ coarse stage controller 412 and thereby moves along the X axis guide rail 160 to the sample measurement station M (S703).

After the XYZ coarse movement stage unit 110 moves along the X axis guide rail 160 to the sample measurement station M, the Z fine movement stage 123 of the XYZ fine movement stage unit 120 is controlled by the XYZ minor stage controller 411 and moved up so that a gap between the upper surface of the row bar 1 and the first probe 132 attached to the cantilever 131 and located near the edge of the cantilever 131 is equal to a predetermined amount (S704).

After the row bar 1 is set as described above, the vertical observation camera 151 images the cantilever 131 and the row bar 1. The controller 440 processes an image obtained by imaging the cantilever 131 and the row bar 1 and calculates a deviation of a part (to be observed) of the upper surface of the row bar 1 from the first probe 132. Then, the controller 440 controls the XYZ coarse movement stage unit 110 through the XYZ coarse movement stage controller 412 or controls the XYZ fine movement stage unit 120 through the XYZ fine movement stage controller 411 and thereby brings roughly the first probe 132 in a region to be observed (S705).

Next, the lateral observation camera 152 images the head part of the second probe 142 and a side surface (left surface of the row bar 1 in FIG. 3 or 6) of the row bar 1 on which the electrodes are formed. Then, the controller 440 processes thus obtained image to detect the level of closeness between the second probe 142 and the row bar 1, the position of the side surface of the row bar 1, a serial number of the row bar 1 and the like. And the controller 440 controls the XYZ coarse movement stage unit 110 through the XYZ coarse movement stage controller 412 or controls the XYZ fine movement stage unit 120 through the XYZ fine movement stage controller 411 and thereby corrects the position of the row bar 1 so that the row bar 1 is located at a predetermined measurement position (S706). The image acquired by the lateral observation camera 152 may be displayed on a screen of the display unit 450.

Then, the tips 1421 and 1422 of the second probe 142 contact surfaces of the electrodes 11 and 12 formed on the row bar 1 (S707). While the first probe 132 is vibrated at a predetermined amplitude, the alternating current source 143 applies an alternating current through the second probe 142 and the electrodes 11 and 12 to the writing circuit 13 so that a magnetic field is generated (S708). In this state, the oscillator 401 excites the vibration exciter 133, and whereby the vibration exciter 133 vibrates the cantilever 131. The vibration of the cantilever 131 causes the first probe 132 (attached to the cantilever 131 and located near the head of the cantilever 131) to vibrate. Then, the XYZ fine movement stage controller 411 drives the X fine movement stage 121 and the Y fine movement stage 122 and causes the X and Y fine movement stages 121 and 122 to move the row bar 1 in X and Y directions, and whereby the first probe 132 scans a region of an upper surface of the writing circuit 13 (S709).

Since the whole inspection apparatus is covered with the sound insulation box 600, the sound insulation box 600 prevents noise caused by sound noise coming from the outside of the apparatus from affecting the cantilever 131 and the first probe 132. In addition, the vibration isolation table 500 blocks a vibration occurred outside the apparatus and thereby prevents noise from affecting the cantilever 131 and the first probe 132. Thus, the apparatus is capable of measuring the row bar 1 with high accuracy.

While the magnetic field is generated from the writing circuit 13, the position detector 134 detects a deviation of the part (to be observed) of the upper surface of the row bar 1 from the first probe 132 located near the head of the cantilever 131 and transmits a detected signal to the amplifier 402. The amplifier 402 amplifies the detected signal and transmits the amplified detected signal to the controller 440. The controller 440 processes the detected signal and calculates an effective track width of a write track of a magnetic head device then compares the calculated effective track width with a set standard width range and thereby determines whether the effective track width is valid (S710). Specifically, when the measured effective track width of the write track is in the standard width range, the effective track width is valid. When the measured effective track width of the write track is not in the standard width range, the effective track width is invalid. The result of the determination is input to and stored in the controller 440.

After the detected signal is transmitted to the amplifier 402, the vibration of the cantilever 131 is stopped, and the tips 1421 and 1422 of the second probe 142 are separated from the surfaces of the electrodes 11 and 12 formed on the row bar 1 (S711). Then, the XYZ fine movement stage controller 411 controls the Z fine movement stage 123 and thereby causes the Z fine movement stage 123 to move down so that a gap between the row bar 1 and the first probe 132 is sufficient (S712).

Next, whether or not all the magnetic head devices formed on the row bar 1 have been measured is checked (S713). When any magnetic head device of the row bar 1 is yet to be measured (No in S713), the XYZ coarse movement stage controller 412 drives the X coarse movement stage 111 or the XYZ fine movement stage controller 411 drives the X fine movement stage 121 so as to move the row bar 1 by one pitch and cause electrodes 11 and 12 of the next head device of the row bar 1 to move to the edges 1421 and 1422 of the second probe 142 (S714). Then, operations S704 to S712 are repeated.

After all the magnetic head devices of the row bar 1 are completely measured (Yes in S713), the XYZ coarse movement stage controller 412 drives the X coarse movement stage 111 so as to move the measured row bar 1 from the sample measurement station M to the sample reception/delivery station H (S715). The transporting robot 310 carries the measured row bar 1 out of the XYZ fine movement stage unit 120 (S716). When the measured row bar 1 is determined as a non-defective product, the transporting robot 310 places the row bar 1 on the tray 332 for non-defective products on the basis of the result of the measurement (S717). When the measured row bar 1 is determined as a defective product, the transporting robot 310 places the row bar 1 on the tray 333 for defective products on the basis of the result of the measurement (S717).

The series of operations 5701 to 5717 are repeatedly performed until all row bars 1 are carried out of the supply tray 331 of the tray holder 330 (S718).

When the row bar 1 is measured, determined as a non-defective product and placed on the tray 332 for non-defective products, the row bar 1 is transported to a location at which the next process of manufacturing magnetic head devices is performed. Then, the row bar 1 is processed in the next process. On the other hand, when the row bar 1 is determined as a defective product and placed on the tray 333 for defective products, the row bar 1 is not transported to the location (at which the next process is performed) and is discarded or transported to a location at which a process of analyzing a defective product is performed in order to identify a cause of a defect.

The above embodiment describes that the alternating current is applied through the second probe 142 to the electrodes 11 and 12 of the magnetic head device formed on the row bar 1 so that the magnetic field is generated from the writing circuit 13. In addition, the embodiment describes the method for measuring the state of the magnetic head device formed on the row bar 1 through the method (i.e., the method using the magnetic force microscope (MFM)) for vibrating and scanning the first probe 132 and measuring the vibration of the first probe 132 while the magnetic field is generated from the writing circuit 13. The embodiment, however, can be applied to the case where the state of the magnetic head device formed on the row bar 1 is measured using a method (i.e., a method using an atomic force microscope (AFM)) that vibrates and scans the first probe 132 to cause the probe 132 to contact the row bar 1 and measures the vibration of the first probe 132 without applying the alternating current through the second probe 142 to the electrodes 11 and 12 of the magnetic head device formed on the row bar 1 while a magnetic field is not generated from the writing circuit 13.

The invention may be embodied in other specific forms without departing from the spirit or essential characteristics thereof. The present embodiment is therefore to be considered in all respects as illustrative and not restrictive, the scope of the invention being indicated by the appended claims, rather than by the foregoing description, and all changes which come within the meaning and range of equivalence of the claims are therefore intended to be embraced therein.

1. An apparatus for inspecting a magnetic head device, comprising:
A tray unit that stores an inspected row bar and an uninspected row bar in a separate manner;
a stage unit capable of moving between an inspection position and a sample reception/delivery position;
a sample receiving and delivering unit that takes out the uninspected row bar from the tray unit and delivers the row bar to the stage unit waiting at the sample reception/delivery position;
a magnetic field measuring unit in which an alternating current is applied to a magnetic head device formed on the uninspected row bar and a magnetic field generated therefrom is measured in a state where the stage unit that received the uninspected row bar at the sample reception/delivery position has moved to the inspection position;
an effective track width measuring unit that determines, on the basis of data obtained from the measurement by the magnetic field measuring unit, whether or not an effective track width of a write track formed on the magnetic head device is valid;
a vibration isolation table that mounts thereon the tray unit, the stage unit, the sample receiving and delivering unit, the magnetic field measuring unit and the effective track width measuring unit, the vibration isolation table adapted to block vibration from the outside of the apparatus; and
a sound insulation unit that covers the tray unit, the stage unit, the sample receiving and delivering unit, the magnetic field measuring unit, the effective track width measuring unit, and the vibration isolation table to insulate noise from the outside of the apparatus.

2. The apparatus for inspecting a magnetic head device according to claim 1, further comprising
a guide rail that guides the stage unit that moves between the inspection position and the sample reception/delivery position,
wherein the stage unit has a linear motor and is driven by the linear motor so as to move along the guide rail between the inspection position and the sample reception/delivery position.

3. The apparatus for inspecting a magnetic head device according to claim 1,
wherein the sample receiving and delivering unit has a vacuum suction head and uses the vacuum suction head to vacuum-suck the uninspected row bar stored on the tray unit so as to take out the uninspected row bar from the tray unit, and delivers the uninspected row bar to the stage unit waiting at the sample reception/delivery position.

4. The apparatus for inspecting a magnetic head device according to claim 1,
wherein the sample receiving and delivering unit has hooks for hanging thereon the uninspected row bar stored on the tray unit and hangs the uninspected row bar on the hooks so as to take out the uninspected row bar from the tray unit, and delivers the uninspected row bar to the stage unit waiting at the sample reception/delivery position.

5. The apparatus for inspecting a magnetic head device according to claim 1,
wherein the magnetic field measuring unit has an observation unit for observing the uninspected row bar placed on the stage unit and uses the stage unit to adjust the position of the uninspected row bar on the basis of information of the position of the uninspected row bar observed by the observation unit.

6. A method for inspecting a magnetic head device, comprising the steps of:
taking out an uninspected row bar from a supply tray and delivering the uninspected row bar to a stage waiting at a sample reception/delivering position;
moving, to an inspection position, the stage that has received the uninspected row bar;
moving up the uninspected row bar by means of the stage so that a gap between the uninspected row bar and a probe attached to a cantilever of a magnetic force microscope and located near an edge of the cantilever, while the stage has moved to the inspection position;
applying an alternating current to one of magnetic head devices formed on the uninspected row bar to cause a magnetic field to be generated from the one of the magnetic head devices, and measuring the state of the generated magnetic field by means of the magnetic force microscope, while the uninspected row bar has been moved up;
determining, on the basis of the measured state of the magnetic field, whether or not an effective track width of a write track formed on the one of the magnetic head devices is valid;
moving down the row bar whose validity of the write track of the magnetic head is determined by means of the stage after the effective track width of the write track has been determined;
using the stage to transport the validity determined row bar from the inspection position to the sample reception/delivery position after the validity determined row bar has been moved down; and
storing, on the basis of the determination of whether the effective track width of the write track is valid, the validity determined row bar transported to the sample reception/delivery position on either a tray for storing a non-defective product or a tray for storing a defective product on a vibration isolation table for blocking a vibration from the outside of the apparatus in an environment in which the apparatus is covered with a sound insulation wall.

7. The method for inspecting a magnetic head device according to claim 6,
wherein the stage is driven by a linear motor so as to move along a guide rail between the inspection position and the sample reception/delivery position.

8. The method for inspecting a magnetic head device according to claim 6, further comprising the step of
using a vacuum suction head to vacuum-suck the uninspected row bar stored on the tray so as to take out the uninspected row bar from the tray, and delivering the uninspected row bar to the stage waiting at the sample reception/delivery position.

9. The method for inspecting a magnetic head device according to claim 6, further comprising the step of
hanging, on hooks, the uninspected row bar stored on the tray so as to take out the uninspected row bar from the tray, and delivering the uninspected row bar to the stage waiting at the sample reception/delivery position.

10. The method for inspecting a magnetic head device according to claim 6, further comprising the step of
using an observation unit to observe the uninspected row bar placed on the stage and using the stage to adjust the position of the uninspected row bar on the basis of information of the position of the observed row bar.
